(19) United States
(12) Patent Application Publication
(10) Pub. No.: US 2011/0006851 A1
(43) Pub. Date: Jan. 13, 2011

(54) Unit inverter having linearly varying delay response characteristic and digitally controlled oscillator including the unit inverter

(75) Inventor: Bong-jin Kim, Suwon-si (KR)

Correspondence Address: MILLS & ONELLO LLP, ELEVEN BEACON STREET, SUITE 605, BOSTON, MA, 02108, US

(73) Assignee: Samsung Electronics Co., LTD., Suwon-si (KR)

(21) Appl. No.: 12/661,934

(22) Filed: Mar. 26, 2010

(30) Foreign Application Priority Data
Jul. 9, 2009 (KR) 10-2009-0062567

(51) Int. Cl. H03K 3/03

(52) U.S. Cl. 331/57

(57) ABSTRACT

A Digitally Controlled Oscillator (DCO) including a unit inverter cell whose output frequency linearly varies according to a digital control signal, the unit inverter cell linearly varying a delay response characteristic of an output signal with respect to an input signal supplied from an input terminal, in response to a reference signal and a zero^{th} control signal, and including a reference cell and a first selecting cell. The reference cell transmits the output signal to an output terminal, wherein the output signal is obtained by reversing a phase of the input signal in response to the reference signal and a reverse reference signal obtained by reversing a phase of the reference signal. The number of transistors forming the reference cell and the first selecting cell and sizes of the transistors are equal.

### CROSS-REFERENCE TO RELATED APPLICATIONS

This application claims the benefit of Korean Patent Application No. 10-2009-0062567, filed on Jul. 9, 2009, in the Korean Intellectual Property Office, the disclosure of which is incorporated herein in its entirety by reference.

### FIELD OF INTEREST

The inventive concepts relate to a digitally controlled oscillator (DCO) and a unit invert cell included in the DCO, and more particularly, to a DCO including a unit inverter cell having an output frequency that linearly varies according to a digital control signal.

### BACKGROUND

A DCO is a device that generates a signal having a constant frequency. The DCO includes an inverter chain that delays an input signal for a predetermined amount of time, digital code includes information about selection of a delay signal output via an inverter from among a plurality of inverters in the inverter chain, and thus the DCO generates a signal having a frequency determined according to the selected delay signal.

A constant temporal delay may occur between a signal that is input to a circuit and a signal that is output from the circuit. In the case of an inverter, a constant gate delay time exists due to a transistor included in the inverter and, thus, there is a response delay between an input signal and an output signal. When the inverter is used as a delay device, the gate delay time may be purposefully used, and in general, a capacitor or a resistor may be connected to an output terminal of the inverter so as to obtain a larger delay time.

In the case of a DCO, a capacitor or a resistor is additionally connected to an output terminal of an inverter to be used as a delay device, and resistance or capacitance is varied according to digital code, to adjust a frequency of an output signal. There may be various methods that involve varying resistance or capacitance according to the digital code, but in general, resistance and capacitance at the output terminal is varied by turning on or off switches disposed between resistors and the output terminal, and between capacitors and the output terminal.

In general, the resistance of a resistor of a unit device and the capacitance of a capacitor of the unit device may deviate, and in the case where the unit device is integrated into a semiconductor, the deviation increases compared to the unit device, and such deviation becomes the cause that prevents determination of a correct delay time. Also, since a passive element has to be additionally mounted on the semiconductor, an area of an oscillator becomes larger, and the range of oscillation frequency is limited by the added passive element.

Thus, there is a demand for an oscillator that does not use a passive element causing the aforementioned disadvantages and that generates an output signal having a frequency that varies according to a change of digital code. In particular, the oscillator has to generate the output signal having a frequency that linearly varies according to the digital code.

### SUMMARY

According to an aspect of the inventive concept, there is provided a unit inverter cell that linearly varies a delay response characteristic of an output signal with respect to an input signal supplied to an input terminal, in response to a reference signal and a zero^{th} control signal. The unit inverter cell includes: a reference cell that transmits the output signal to an output terminal, wherein the output signal is obtained by inverting a phase of the input signal in response to the reference signal and a reverse reference signal obtained by inverting a phase of the reference signal; and a first selecting cell that generates the output signal by inverting the phase of the input signal in response to the zero^{th} control signal and a zero^{th} reverse control signal obtained by inverting a phase of the zero^{th} control signal, wherein the number of transistors forming the reference cell and the first selecting cell and sizes of the transistors are equal.

In some unit inverter cell implementations, the reference cell can include: a first reference switch that applies a first reference voltage to a first terminal of the first reference switch, in response to the reverse reference signal; a second reference switch that applies a second reference voltage to a first terminal of the second reference switch, in response to the reference signal; a first inverter transistor comprising a first terminal connected to a second terminal of the first reference switch, a second terminal connected to the output terminal, and a gate to which the input signal is applied; and a second inverter transistor comprising a first terminal connected to the output terminal, a second terminal connected to a second terminal of the second reference switch, and a gate to which the input signal is applied. The first selecting cell can include: a first selecting switch that applies the first reference voltage to a first terminal of the first selecting switch, in response to the zero^{th} reverse control signal; a second selecting switch that applies the second reference voltage to a first terminal of the second selecting switch, in response to the zero^{th} control signal; a third inverter transistor comprising a first terminal connected to a second terminal of the first reference switch, a second terminal connected to the output terminal, and a gate to which the input signal is applied; and a fourth inverter transistor comprising a first terminal connected to the output terminal, a second terminal connected to a second terminal of the second selecting switch, and a gate to which the input signal is applied. A turn-on resistance value of the first reference switch and a turn-on resistance value of the second reference switch can be respectively equal to a turn-on resistance value of the first inverter transistor and a turn-on resistance value of the second inverter transistor, or the turn-on resistance value of the first reference switch, the turn-on resistance value of the second reference switch, the turn-on resistance value of the first inverter transistor, and the turn-on resistance value of the second inverter transistor can be equal to each other. And a turn-on resistance value of the first selecting switch and a turn-on resistance value of the second selecting switch can be respectively equal to a turn-on resistance value of the third inverter transistor and a turn-on resistance value of the fourth inverter transistor, or the turn-on resistance value of the first selecting switch, the turn-on resistance value of the second selecting switch, the turn-on resistance value of the third inverter transistor, and the turn-on resistance value of the fourth inverter transistor can be equal to each other.

Optionally, the first reference switch and the second reference switch can always be turned on.

In some implementations, the unit inverter cell can further comprise a second selecting cell operating in response to a first control signal and a first reverse control signal obtained by inverting a phase of the first control signal, and N^{th} selecting cells (where N≧3) respectively operating in response to N^{th} control signals and N^{th} reverse control signals obtained by inverting phases of the Nth control signals. Here, a number of devices forming the second selecting cell and the N^{th} selecting cells can be the same as those of the first selecting cell. Turn-on resistance values of the devices forming the second selecting cell can be half turn-on resistance values of devices forming the first selecting cell. And turn-on resistance values of devices forming the N^{th} selecting cells can be half turn-on resistance values of devices forming the (N−1)^{th} selecting cells.

In some implementations of the unit inverter cell, the first reference voltage can have a voltage level higher than that of the second reference voltage, and the second reference voltage can be a ground voltage.

According to another aspect of the inventive concept, there is provided a unit inverter cell including a reference cell, and N selecting cells, where N is an integer equal to or greater than 1. The reference cell generates an output signal obtained by inverting a phase of an input signal. The N selecting cells generate the output signal by inverting the phase of the input signal. Here, a number of devices forming the N selecting cells and a number of devices forming the reference cell are the same. And turn-on resistance values of devices forming an N^{th} selecting cell are half turn-on resistance values of devices forming an (N−1)^{th} selecting cell.

In some implementations of the unit inverter cell, a size of devices forming a first selecting cell, from the N selecting cells, is the same as a size of the devices forming the reference cell; a size of devices forming a second selecting cell, from the N selecting cells, is twice the size of the devices forming the first selecting cell; and a size of the devices forming each Nth selecting cell is twice a size of devices forming a corresponding (N−1)^{th} selecting cell.

In some implementations of the unit inverter cell, the reference cell can include: a first reference switch that applies a first reference voltage to a first terminal of the first reference switch, in response to a reverse reference signal obtained by reversing a phase of a reference signal; a second reference switch that applies a second reference voltage to a first terminal of the second reference switch, in response to the reference signal; a first inverter transistor including a first terminal connected to a second terminal of the first reference switch, a second terminal connected to an output terminal, and a gate to which the input signal is applied; and a second inverter transistor including a first terminal connected to the output terminal, a second terminal connected to a second terminal of the second reference switch, and a gate to which the input signal is applied. A turn-on resistance value of the first reference switch and a turn-on resistance value of the second reference switch can be respectively equal to a turn-on resistance value of the first inverter transistor and a turn-on resistance value of the second inverter transistor, or the turn-on resistance value of the first reference switch, the turn-on resistance value of the second reference switch, the turn-on resistance value of the first inverter transistor, and the turn-on resistance value of the second inverter transistor can be equal.

Optionally, the first reference switch and the second reference switch can be always turned on.

In some implementations of the unit inverter cell, N is equal to the number of bits of a control signal. Here, a first selecting cell operates in response to a first control signal and a first reverse control signal obtained by inverting a phase of the first control signal. A second selecting cell operates in response to a second control signal and a second reverse control signal obtained by inverting a phase of the second control signal. And the N selecting cells operate in response to Nth control signals and Nth reverse control signals respectively obtained by inverting phases of the Nth control signals.

According to another aspect of the inventive concept, there is provided a digitally controlled oscillator (DCO), which includes an inverter chain circuit generated by connecting in series unit inverter cells. Each unit inverter cell includes a reference cell that generates an output signal obtained by reversing a phase of an input signal; and N selecting cells (N is an integer equal to or greater than 1) that generates the output signal by reversing the phase of the input signal. In each of the unit inverter cells, the number of devices forming the N selecting cells is the same as the number of devices forming the reference cell. And turn-on resistance values of devices forming an Nth selecting cell are half turn-on resistance values of devices forming an (N−1)^{th} selecting cell.

In some implementations, for each of the unit inverter cells, a size of devices forming a first selecting cell, from the N selecting cells, is the same as a size of the devices forming the reference cell; a size of devices forming a second selecting cell, from the N selecting cells, is twice the size of the devices forming the first selecting cell; and a size of the devices forming each Nth selecting cell is twice a size of devices forming a corresponding (N−1)^{th} selecting cell.

### BRIEF DESCRIPTION OF THE DRAWINGS

The inventive concept will be more clearly understood from the following detailed description of exemplary embodiments taken in conjunction with the accompanying drawings in which:

FIG. 1 is a diagram of an embodiment of an inverter chain that uses a resistor and a capacitor as a load, according to aspects of the inventive concept;

FIG. 2 is a diagram of an embodiment of a unit inverter cell, according to aspects of the inventive concept;

FIG. 3 is an internal circuit diagram of an embodiment of a first selecting cell of the unit inverter cell of FIG. 2;

FIG. 4 is an embodiment of an equivalent circuit of the first selecting cell of the unit inverter cell of FIG. 2;

FIG. 5 is a graph showing a frequency characteristic of an output signal of a conventional DCO according to variation of digital code; and

FIG. 6 is a graph showing a frequency characteristic of an output signal of a digitally controlled oscillator (DCO) according to variation of digital code, according to aspects of the inventive concept.

### DETAILED DESCRIPTION OF THE EMBODIMENTS

Hereinafter, exemplary embodiments in accordance with aspects of the inventive concept will be described with reference to the attached drawings. Like reference numerals in the drawings denote like elements.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

FIG. 1 is a diagram of an embodiment of an inverter chain 100 that uses a resistor and a capacitor as a load.

Referring to FIG. 1, the inverter chain 100 includes three inverters 101-103 (hereinafter, referred to as “the first, second, and third inverters 101-103”), two resistors R1 and R2 (hereinafter, referred to as “the first and second resistors R1 and R2), and two capacitors C1 and C2 (hereinafter, referred to as “the first and second capacitors C1 and C2). The first, second, and third inverters 101-103 are connected in series and form a chain in such a manner that inputs and outputs of the first, second, and third inverters 101-103 are connected to each other, and the resistors R1 and R2 and the capacitors C1 and C2 are connected to output terminals of the first, second, and third inverters 101-103 as loads.

A response delay time between an input signal output from an output terminal of the third inverter 103 and applied to an input terminal of the first inverter 101 and a signal output from an output terminal of the first inverter 101 is determined by not only a delay time of a device forming the first inverter 101, but also by values of the first resistor R1 and the first capacitor C1 connected to the output terminal of the first inverter 101.

In the circuit illustrated in FIG. 1, as described above, the resistor and the capacitor, which have a predetermined size, are added to the output terminals of the first, second, and third inverters 101-103 forming the inverter chain 100, such that an area occupied by the inverter chain 100 is increased. Therefore, the area occupied by the resistor and the capacitor contributes to the area occupied by the inverter chain 100, and thus may contribute to an area occupied an oscillator. In addition, a considerable amount of power is consumed by an oscillator including the resistors R1 and R2 and the capacitors C1 and C2. Thus, in the case of a system having small power consumption, the oscillator including the inverter chain 100 consuming the considerable amount of power may not be used in the system.

One or more embodiments of the inventive concept provide a digitally controlled oscillator (DCO) in which a response characteristic of an output signal with respect to an input signal varies according to digital code, and in particular, the response characteristic linearly varies according to linear variation of the digital code. The DCO includes an inverter chain by which a response characteristic of an output signal of an arbitrary inverter forming the inverter chain is to linearly vary according to the linear variation of the digital code. Hereinafter, a unit inverter cell for allowing the inverter chain to have such a delay response characteristic will now be described.

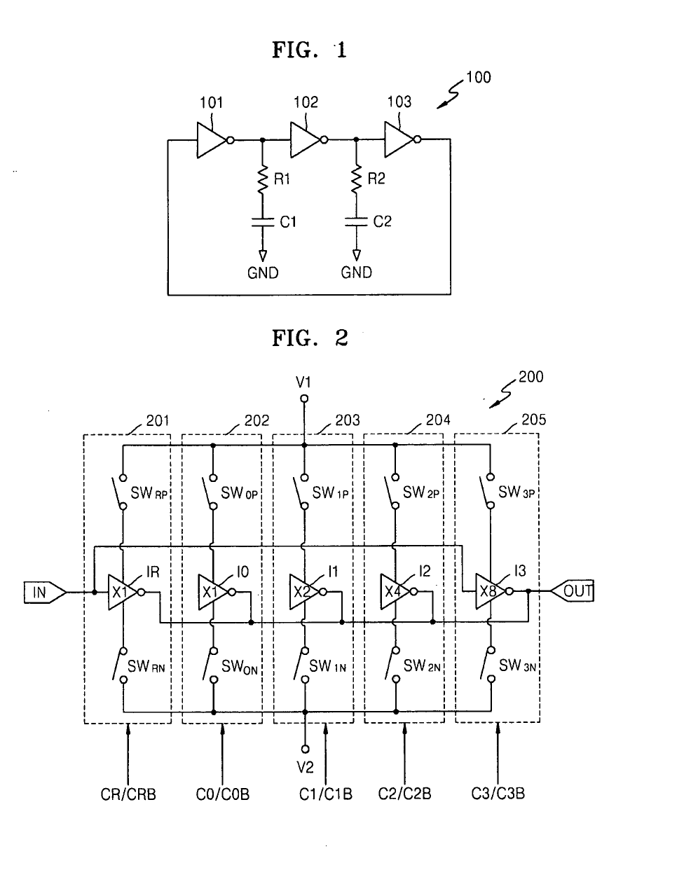

FIG. 2 is a diagram of an embodiment of a unit inverter cell 200, according to an embodiment of the inventive concept.

Referring to FIG. 2, the unit inverter cell 200 may linearly vary a response characteristic of an output signal with respect to an input signal that may be supplied to an input terminal IN, in response to a reference signal CR and four control signals C0-C3 (hereinafter, referred to as “the zero^{th} through third control signals C0-C3”), and includes a reference cell 201 and first through fourth selecting cells 202-205.

The reference cell 201 inverts a phase of the input signal, in response to the reference signal CR and a reverse reference signal CRB that is obtained by inverting a phase of the reference signal CR. The four selecting cells 202-205 inverts the phase of the input signal respectively in response to the zero^{th} through third control signals C0-C3 and zero^{th} reverse control signal through third reverse control signals C0B-C3B that are obtained by respectively inverting phases of the zero^{th} through third control signals C0-C3.

The reference cell 201 includes a first reference switch SW_{RP} that switches a first reference voltage V1 in response to the reverse reference signal CRB, a second reference switch SW_{RN} that switches a second reference voltage V2 in response to the reference signal CR, and a reference inverter IR that inverts the phase of the input signal according to being supplied the first reference voltage V1 and the second reference voltage V2, which may be supplied via the first and second reference switches SW_{RP} and SW_{RN}.

The first selecting cell 202 includes a first selecting switch SW_{0P} that switches the first reference voltage V1 in response to the zero^{th} reverse control signal C0B, a second selecting switch SW_{0N} that switches the second reference voltage V2 in response to the zero^{th} control signal C0, and a first selecting inverter I0 that inverts the phase of the input signal according to the existence of the first reference voltage V1 and the second reference voltage V2, which may be supplied via the first and second selecting switches SW_{0P} and SW_{0N}.

The second selecting cell 203 includes a third selecting switch SW_{1P} that switches the first reference voltage V1 in response to the first reverse control signal C1B, a fourth selecting switch SW_{1N} that switches the second reference voltage V2 in response to the first control signal C1, and a second selecting inverter I1 that inverts the phase of the input signal according to the existence of the first reference voltage V1 and the second reference voltage V2, which may be supplied via the third and fourth selecting switches SW_{1P} and SW_{1N}.

The third selecting cell 204 includes a fifth selecting switch SW_{2P} that switches the first reference voltage V1 in response to the second reverse control signal C2B, a sixth selecting switch SW_{2N} that switches the second reference voltage V2 in response to the second control signal C2, and a third selecting inverter I2 that inverts the phase of the input signal according to the existence of the first reference voltage V1 and the second reference voltage V2, which may be supplied via the fifth and sixth selecting switches SW_{2P} and SW_{2N}.

The fourth selecting cell 205 includes a seventh selecting switch SW_{3P} that switches the first reference voltage V1 in response to the third reverse control signal C3B, an eighth selecting switch SW_{3N} that switches the second reference voltage V2 in response to the third control signal C3, and a fourth selecting inverter I3 that inverts, the phase of the input signal according to the existence of the first reference voltage V1 and the second reference voltage V2, which may be supplied via the seventh and eighth selecting switches SW₃ₚ and SW_{3N}.

X1 marked within the reference inverter IR and X1, X2, X4, and X8 respectively marked within the first through fourth selecting inverters I0-I3 respectively indicate a physical size of transistors forming the reference inverter IR and the first through fourth selecting inverters I0-I3. Here “X” can indicate a base size and the number associated with X can indicate a multiple of X, e.g., X2 can indicate 2 times X. It is possible to see that the physical size of transistors increases in the order from the first to fourth selecting inverters I0-I3 by powers of 2. The physical size of a transistor may indicate a ratio of a gate width W to a gate length L (W/L) of the transistor. When the ratio (W/L) of the gate width W to the gate length L is relatively large, a turn-on resistance value of the transistor is relatively small. Thus, it is possible to see that turn-on resistance values of transistors forming the first selecting inverter I0 are half those of transistors forming the second selecting inverter I1.

In addition, although not illustrated in FIG. 2, a turn-on resistance value of a transistor from among two transistors forming the reference inverter IR of the reference cell 201 is the same as a turn-on resistance value of the first reference switch SW_{RP}, and a turn-on resistance value of the other transistor from among the two transistors is the same as a turn-on resistance value of the second reference switch SW_{RN}.

A turn-on resistance value of a transistor from among two transistors forming the first selecting inverter I0 of the first selecting cell 202 is the same as a turn-on resistance value of the first selecting switch SW_{0P}, and a turn-on resistance value of the other transistor from among the two transistors is the same as a turn-on resistance value of the second selecting switch SW_{0N}. A turn-on resistance value of a transistor from among two transistors forming the second selecting inverter I1 of the second selecting cell 203 is the same as a turn-on resistance value of the third selecting switch SW_{1P}, and a turn-on resistance value of the other transistor from among the two transistors is the same as a turn-on resistance value of the fourth selecting switch SW_{1N}. A turn-on resistance value of a transistor from among two transistors forming the third selecting inverter I2 of the third selecting cell 204 is the same as a turn-on resistance value of the fifth selecting switch SW_{2P}, and a turn-on resistance value of the other transistor from among the two transistors is the same as a turn-on resistance value of the sixth selecting switch SW_{2N}. A turn-on resistance value of a transistor from among two transistors forming the fourth selecting inverter I3 of the fourth selecting cell 204 is the same as a turn-on resistance value of the seventh selecting switch SW_{3P}, and a turn-on resistance value of the other transistor from among the two transistors is the same as a turn-on resistance value of the eighth selecting switch SW_{3N}.

According to another embodiment, the turn-on resistance values of the two transistors forming the reference cell 201 may have the same turn-on resistance value, and likewise, the turn-on resistance values of the two transistors forming the first selecting cell 202 may have the same turn-on resistance value. Likewise, the turn-on resistance values of all transistors forming the second through fourth selecting cells 203 through 205 may have the same turn-on resistance value as corresponding transistors in a corresponding cell.

The turn-on resistance values of the third and fourth selecting switches SW_{1P} and SW_{1N} forming the second selecting cell 203 and the turn-on resistance values of the two transistors forming the second selecting inverter I1 are half the turn-on resistance values of the first and second selecting switches SW_{0P} and SW_{0N} forming the first selecting cell 202 and the turn-on resistance values of the two transistors forming the first selecting inverter I0.

The turn-on resistance values of the fifth and sixth selecting switches SW_{2P} and SW_{2N} forming the third selecting cell 204 and the turn-on resistance values of the two transistors forming the third selecting inverter I2 are half the turn-on resistance values of the third and fourth selecting switches SW_{1P} and SW_{1N} forming the second selecting cell 203 and the turn-on resistance values of the two transistors forming the second selecting inverter I1.

Likewise, the turn-on resistance values of the seventh and eight selecting switches SW_{3P} and SW_{3N} forming the fourth selecting cell 205 and the turn-on resistance values of the two transistors forming the fourth selecting inverter I3 are half the turn-on resistance values of the fifth and sixth selecting switches SW_{2P} and SW_{2N} forming the third selecting cell 204 and the turn-on resistance values of the two transistors forming the third selecting inverter I2.

If the first reference voltage V1 and the second reference voltage V2 are not applied to the reference cell 201, the reference inverter IR does not operate, and thus, in order to prevent this, the first reference switch SW_{RP} and the second reference switch SW_{RN} may be always turned on. In this case, the reference signal CR and the reverse reference signal CRB may be set at a fixed bias voltage.

However, the four selecting cells 202-205 may or may not supply the first reference voltage V1 and the second reference voltage V2, respectively, to the first through fourth selecting inverters I0-I3, respectively, according to the zero^{th} through third control signals C0-C3 and the zero^{th} reverse control signal through third reverse control signal C0B-C3B, and thus determine a frequency characteristic of an output signal OUT with respect to an input signal IN of the unit inverter cell 200.

Summarizing what was described above, the size of selecting switches and transistors forming an inverter is doubled in the order of the first selecting cell 202, the second selecting cell 203, the third selecting cell 204, and the fourth selecting cell 205, so that the turn-on resistance values of the selecting switches and the transistors forming an inverter are half those of a preceding selecting cell.

In FIG. 2, although voltage levels of the first reference voltage V1 and the second reference voltage V2 are not marked, the first reference voltage V1 has a higher voltage level when compared to that of the second reference voltage V2. The second reference voltage V2 may, for example, be a ground voltage and the first reference voltage may be, for example, a supply voltage, such as V_{DD} or V_{cc}.

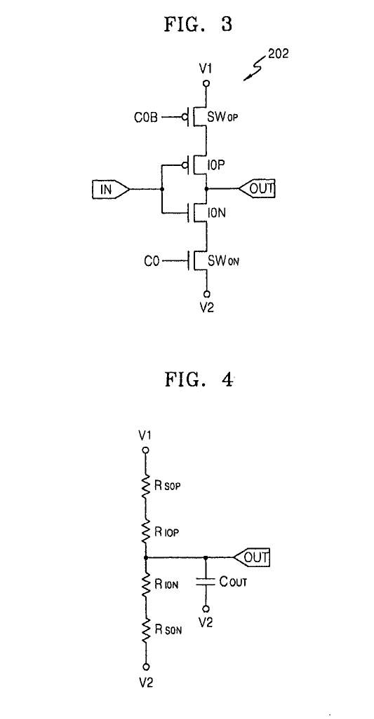

FIG. 3 is an embodiment of an internal circuit diagram of the first selecting cell 202.

Referring to FIG. 3, the first selecting cell 202 includes the first selecting switch SW_{0P}, a first inverter transistor I0P, a second inverter transistor I0N, and the second selecting switch SW_{0N}.

The first selecting switch SW_{0P} switches the first reference voltage V1 to a first terminal of the first inverter transistor I0P, in response to the zero^{th} reverse control signal C0B. The second selecting switch SW_{0N} switches the second reference voltage V2 to a first terminal of the second inverter transistor I0N, in response to the zero^{th} control signal C0. The first inverter transistor I0P outputs an output signal OUT to a second terminal of I0P, wherein the output signal OUT is obtained by inverting a phase of an input signal IN that is applied to a gate of I0P according to existence of the first reference voltage V1 supplied to the first terminal of I0P. The second inverter transistor I0N outputs an output signal OUT to a second terminal of I0N, wherein the output signal OUT is obtained by inverting a phase of an input signal IN that is applied to a gate of I0N according to existence of the second reference voltage V2 supplied to the first terminal of I0N.

For convenience of description, only the first selecting cell 202 is illustrated in FIG. 3, because the reference cell 201, the second selecting cell 203, the third selecting cell 204, and the fourth selecting cell 205, which are illustrated in FIG. 2, may have the same structure.

FIG. 4 is another embodiment of an equivalent circuit of the first selecting cell 202.

Referring to FIG. 4, it is already described that a turn-on resistance value R_{S0P} of the first selecting switch SW_{0P} is equivalent to a turn-on resistance value R_{I0P} of the first inverter transistor I0P, and a turn-on resistance value R_{S0N} of the second selecting switch SW_{0N} is equivalent to a turn-on resistance value R_{I0N} of the second inverter transistor I0N. However, since turn-on resistance values of two transistors forming an ideal inverter are equal to each other, the turn-on resistance values R_{S0P} and R_{S0N} of the first and second selecting switches SW_{0P} and SW_{0N} and the turn-on resistance values R_{I0P} and R_{I0N} of the first and second inverter transistors I0P and I0N may be equal to each other. Likewise, the reference cell 201, the second selecting cell 203, the third selecting cell 204, and the fourth selecting cell 205 may be set in the same manner as the first selecting cell 202.

A frequency response characteristic of the first selecting cell 202 shown in FIGS. 3 and 4 is defined as Equation 1.

$${f}_{OSC} = \frac{1}{{t}_{PLH} + {t}_{PHL}} \\ {t}_{PLH} ≅ 0.7 ( {R}_{S0P} + {R}_{I 0 P} ) \times {C}_{OUT} \\ {t}_{PHL} ≅ 0.7 ( {R}_{S 0 N} + {R}_{I 0 N} ) \times {C}_{OUT} \qquad [ Equation 1 ]$$

When the turn-on resistance value R_{S0P} of the first selecting switch SW_{0P} and the turn-on resistance value R_{S0N} of the second selecting switch SW_{0N} are defined as Rₛ, and the turn-on resistance value R_{I0P} of the first inverter transistor I0P and the turn-on resistance value R_{I0N} of the second inverter transistor I0N are defined as R₁, the frequency response characteristic of the first selecting cell 202 is defined as Equation 2.

$${f}_{OSC} = \frac{1}{1.4 \times ( {R}_{S} + {R}_{I} ) \times {C}_{OUT}} \qquad [ Equation 2 ]$$

where the turn-on resistance value R_{S0P} of the first selecting switch SW_{0P} is equivalent to the turn-on resistance value R_{I0P} of the first inverter transistor I0P, and the turn-on resistance value R_{S0N} of the second selecting switch SW_{0N} is equivalent to the turn-on resistance value R_{I0N} of the second inverter transistor I0N, and thus the frequency response characteristic of the first selecting cell 202 is finally defined as Equation 3.

$${f}_{OSC} = \frac{1}{2.8 \times {R}_{S} \times {C}_{OUT}} \qquad [ Equation 3 ]$$

Referring to Equation 3, it is possible to know that the frequency response characteristic of the first selecting cell 202 linearly varies. In the case where the first selecting cell 202 having such linearity is connected in parallel with the reference cell 201, a frequency response characteristic of the unit inverter cell 200 also has linearity.

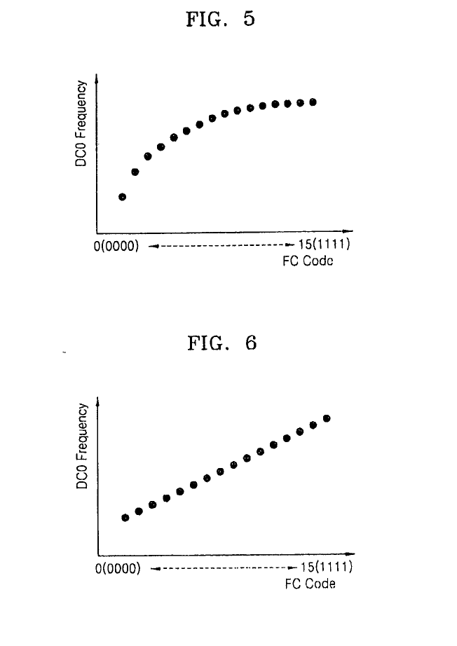

FIG. 5 is a graph showing a frequency characteristic of an output signal of a conventional DCO with respect to variation of digital code.

FIG. 6 is a graph showing a frequency characteristic of an output signal of a DCO with respect to variation of digital code, according to aspects of the present inventive concept.

It is possible to see that the output signal of the conventional DCO illustrated in FIG. 5 has a DCO frequency characteristic that non-linearly varies with respect to the variation of digital code, whereas, in FIG. 6, the output signal of the DCO according to the one or more embodiments of the inventive concept linearly varies with respect to the variation of digital code.

While the inventive concept has been particularly shown and described with reference to exemplary embodiments thereof, it will be understood that various changes in form and details may be made therein without departing from the spirit and scope of the following claims. The present invention therefore, is to be considered described by the claims and should not be limited to the exemplary embodiments described herein.

1. A unit inverter cell that linearly varies a delay response characteristic of an output signal with respect to an input signal supplied to an input terminal, in response to a reference signal and a zero^{th} control signal, the unit inverter cell comprising:
a reference cell for transmitting the output signal to an output terminal, wherein the output signal is obtained by inverting a phase of the input signal in response to the reference signal and a reverse reference signal obtained by inverting a phase of the reference signal; and
a first selecting cell that generates the output signal by inverting the phase of the input signal in response to the zero^{th} control signal and a zero^{th} reverse control signal obtained by inverting a phase of the zero^{th} control signal,
wherein the number of transistors and sizes of the transistors forming the reference cell and the first selecting cell are equal.

2. The unit inverter cell of claim 1, wherein the reference cell comprises:
a first reference switch that applies a first reference voltage to a first terminal of the first reference switch, in response to the reverse reference signal;
a second reference switch that applies a second reference voltage to a first terminal of the second reference switch, in response to the reference signal;
a first inverter transistor comprising a first terminal connected to a second terminal of the first reference switch, a second terminal connected to the output terminal, and a gate to which the input signal is applied; and
a second inverter transistor comprising a first terminal connected to the output terminal, a second terminal connected to a second terminal of the second reference switch, and a gate to which the input signal is applied,
wherein the first selecting cell comprises:
a first selecting switch that applies the first reference voltage to a first terminal of the first selecting switch, in response to the zero^{th} reverse control signal;
a second selecting switch that applies the second reference voltage to a first terminal of the second selecting switch, in response to the zero^{th} control signal;
a third inverter transistor comprising a first terminal connected to a second terminal of the first reference switch, a second terminal connected to the output terminal, and a gate to which the input signal is applied; and
a fourth inverter transistor comprising a first terminal connected to the output terminal, a second terminal connected to a second terminal of the second selecting switch, and a gate to which the input signal is applied,
wherein a turn-on resistance value of the first reference switch and a turn-on resistance value of the second reference switch are respectively equal to a turn-on resistance value of the first inverter transistor and a turn-on resistance value of the second inverter transistor, or
wherein the turn-on resistance value of the first reference switch, the turn-on resistance value of the second reference switch, the turn-on resistance value of the first inverter transistor, and the turn-on resistance value of the second inverter transistor are equal to each other, and
wherein a turn-on resistance value of the first selecting switch and a turn-on resistance value of the second selecting switch are respectively equal to a turn-on resistance value of the third inverter transistor and a turn-on resistance value of the fourth inverter transistor, or
wherein the turn-on resistance value of the first selecting switch, the turn-on resistance value of the second selecting switch, the turn-on resistance value of the third inverter transistor, and the turn-on resistance value of the fourth inverter transistor are equal to each other.

3. The unit inverter cell of claim 2, wherein the first reference switch and the second reference switch are always turned on.

4. The unit inverter cell of claim 1, further comprising a second selecting cell operating in response to a first control signal and a first reverse control signal obtained by inverting a phase of the first control signal, and N^{th} selecting cells (where N≧3) respectively operating in response to N^{th} control signals and N^{th} reverse control signals obtained by inverting phases of the N^{th} control signals,
wherein a number of devices forming the second selecting cell and the N^{th} selecting cells are the same as those of the first selecting cell,
wherein turn-on resistance values of the devices forming the second selecting cell are half turn-on resistance values of devices forming the first selecting cell, and
wherein turn-on resistance values of devices forming the N^{th} selecting cells are half turn-on resistance values of devices forming the (N−1)^{th} selecting cells.

5. The unit inverter cell of claim 1, wherein the first reference voltage has a voltage level higher than that of the second reference voltage, and the second reference voltage is a ground voltage.

6. A unit inverter cell comprising:
a reference cell that generates an output signal obtained by inverting a phase of an input signal; and
N selecting cells (N≧1) that generate the output signal by inverting the phase of the input signal,
wherein a number of devices forming the N selecting cells and a number of devices forming the reference cell are the same, and
wherein turn-on resistance values of devices forming an N^{th} selecting cell are half turn-on resistance values of devices forming an (N−1)^{th} selecting cell.

7. The unit inverter cell of claim 6, wherein:
a size of devices forming a first selecting cell, from the N selecting cells, is the same as a size of the devices forming the reference cell;
a size of devices forming a second selecting cell, from the N selecting cells, is twice the size of the devices forming the first selecting cell; and
a size of the devices forming each N^{th} selecting cell is twice a size of devices forming a corresponding (N−1)^{th} selecting cell.

8. The unit inverter cell of claim 6, wherein the reference cell comprises:
a first reference switch that applies a first reference voltage to a first terminal of the first reference switch, in response to a reverse reference signal obtained by reversing a phase of a reference signal;
a second reference switch that applies a second reference voltage to a first terminal of the second reference switch, in response to the reference signal;
a first inverter transistor comprising a first terminal connected to a second terminal of the first reference switch, a second terminal connected to an output terminal, and a gate to which the input signal is applied; and
a second inverter transistor comprising a first terminal connected to the output terminal, a second terminal connected to a second terminal of the second reference switch, and a gate to which the input signal is applied, and
wherein a turn-on resistance value of the first reference switch and a turn-on resistance value of the second reference switch are respectively equal to a turn-on resistance value of the first inverter transistor and a turn-on resistance value of the second inverter transistor, or
wherein the turn-on resistance value of the first reference switch, the turn-on resistance value of the second reference switch, the turn-on resistance value of the first inverter transistor, and the turn-on resistance value of the second inverter transistor are equal.

9. The unit inverter cell of claim 8, wherein the first reference switch and the second reference switch are always turned on.

10. The unit inverter cell of claim 6, wherein N is equal to the number of bits of a control signal, and
wherein a first selecting cell operates in response to a first control signal and a first reverse control signal obtained by inverting a phase of the first control signal,
wherein a second selecting cell operates in response to a second control signal and a second reverse control signal obtained by inverting a phase of the second control signal, and
wherein the N selecting cells operate in response to N^{th} control signals and N^{th} reverse control signals respectively obtained by inverting phases of the N^{th} control signals.

11. A digitally controlled oscillator (DCO) comprising an inverter chain circuit having a plurality of unit inverter cells connected in series, wherein each of the unit inverter cells comprises a reference cell that generates an output signal obtained by inverting a phase of an input signal; and N selecting cells (N≧1) that generate the output signal by inverting the phase of the input signal,
wherein, in each of the unit inverter cells, a number of devices forming the N selecting cells is the same as a number of devices forming the reference cell, and
wherein turn-on resistance values of devices forming an N^{th} selecting cell are half turn-on resistance values of devices forming an (N−1)^{th} selecting cell.

12. The DCO of claim 11, wherein in each of the unit inverter cells,
a size of devices forming a first selecting cell, from the N selecting cells, is the same as a size of the devices forming the reference cell;
a size of devices forming a second selecting cell, from the N selecting cells, is twice the size of the devices forming the first selecting cell; and
a size of the devices forming each N^{th} selecting cell is twice a size of devices forming a corresponding (N−1)^{th} selecting cell.
